(19) United States
(12) Patent Application Publication
(10) Pub. No.: US 2012/0025260 A1
(43) Pub. Date: Feb. 2, 2012

(54) SEMICONDUCTOR DEVICE

(76) Inventors: Shigehisa OONAKAHARA, Kyoto (JP); Kenichi Ito, Osaka (JP); Tooru Aoyagi, Kyoto (JP); Yuu Hasegawa, Kagoshima (JP)

(21) Appl. No.: 13/190,886

(22) Filed: Jul. 26, 2011

(30) Foreign Application Priority Data
Jul. 27, 2010 (JP) 2010-168433

(51) Int. Cl. H01L 33/62; H01L 31/0203

(52) U.S. Cl. 257/99; 257/433; 257/E33.066; 257/E31.113

(57) ABSTRACT

A semiconductor device includes a lead frame, a first semiconductor element mounted on the lead frame, a frame-like member formed on the lead frame, surrounding the first semiconductor element, and a protective resin filling a space surrounded by the frame-like member. The lead frame has an external terminal protruding outside the frame-like member. The external terminal has a barrier portion which is located at an end portion thereof protruding from the frame-like member and rises from a top surface of the external terminal.

### CROSS-REFERENCE TO RELATED APPLICATION

This application claims priority to Japanese Patent Application No. 2010-168433 filed on Jul. 27, 2010, the disclosure of which including the specification, the drawings, and the claims is hereby incorporated by reference in its entirety.

### BACKGROUND

The present disclosure relates to semiconductor devices, and more particularly, to semiconductor devices including a lead frame.

A variety of semiconductor devices in which a high-luminance and high-power light emitting element, a small-size and high-sensitivity photodetector element, etc. are packaged have been developed. The reduction of the size, power consumption, and weight of the semiconductor devices has progressed significantly. The semiconductor devices are becoming increasingly popular for use as light sources of optical printer heads, light sources of liquid crystal backlights, light sources of indicators, read sensors, etc.

A semiconductor device employing a light emitting diode (LED) has a small size and high efficiency and is capable of emitting light having a vivid color. The semiconductor device is free from burnout, has excellent initial drive characteristics and vibration resistance, and is resistant to repeated turning on/off. Therefore, the use of the semiconductor device as a liquid crystal backlight source of a mobile telephone and a PDA has been studied. However, as the reduction of the thickness and size of a liquid crystal display device has progressed, various problems have arisen in the semiconductor device employing an LED.

In the semiconductor device employing an LED, the LED chip is typically encapsulated in a molded package. Specifically, the LED chip is mounted in a package member made of a resin with external terminals of the LED chip extending outside the package member. A space around the LED chip is filled with a protective resin. There are poor tightness and adhesion between the resin package member and the metal external terminal. Therefore, a gap may occur at an interface between the package member and the external terminal, and the protective resin may leak out through the gap. The protective resin leaking outside the package member may cause burrs during cutting and forming, or various problems, such as solder defects etc.

To reduce or prevent the leakage of the protective resin, it has been contemplated to form a trench or protrusion which serves as a barrier to the protective resin at an interface between the external terminal and the package member (see, for example, Japanese Patent Publication No. 2006-222382).

### SUMMARY

However, the above conventional technique has a problem that the technique addresses only the leakage of the protective resin through the interface between the external terminal and the package member. As the miniaturization of semiconductor devices has progressed, a space filled with the protective resin has become considerably small. Therefore, even if a slight error occurs in the amount of the protective resin filling the gap, the protective resin is likely to leak out of the package member. When a semiconductor device is mounted onto a mounting substrate, a lower surface and side surfaces of the external terminal need to be covered with a solder fillet. If the protective resin flowing over the frame-like member of the package member to leak outside the package member reaches the side surface or lower surface of the external terminal protruding outside the package member, it becomes difficult to form a solder fillet which covers the external terminal, resulting in an incorrect or defective mounting.

Such a problem may arise not only in semiconductor devices employing an LED, but also in any other semiconductor devices.

The present disclosure describes implementations of a semiconductor device in which an incorrect or defective mounting is less likely to occur even if leakage of a protective resin occurs.

An example semiconductor device of the present disclosure has a barrier portion at an end portion of an external terminal.

Specifically, the example semiconductor device includes a lead frame, a first semiconductor element mounted on a main surface of the lead frame, a frame-like member formed on the lead frame, surrounding the first semiconductor element, and a protective resin filling a space surrounded by the frame-like member. The lead frame has an external terminal protruding outside the frame-like member. The external terminal has a barrier portion which is located at an end portion thereof protruding from the frame-like member and rises from the main surface in a direction in which the first semiconductor element is mounted.

According to the example semiconductor device, even if the protective resin which leaks out through a gap between the frame-like member and the lead frame and the protective resin which flows over the frame-like member spread on a top surface of the external terminal, the protective resin is less likely to reach a front-end surface and a bottom surface of the external terminal. Therefore, a problem that the external terminal is not covered with a solder fillet is less likely to occur.

### BRIEF DESCRIPTION OF THE DRAWINGS

FIG. 1A is a plan view of a structure of a semiconductor device according to an embodiment.

FIG. 1B is a cross-sectional view of the structure of the semiconductor device, taken along line Ib-Ib of FIG. 1A.

FIG. 1C is a bottom view of the structure of the semiconductor device.

FIG. 2 is a perspective view showing a variation of a barrier portion.

FIG. 3 is a perspective view showing a variation of the barrier portion.

FIG. 4 is a perspective view showing a variation of the barrier portion.

FIG. 5 is a perspective view showing a variation of the barrier portion.

FIGS. 6A-6C are cross-sectional views showing variations of an external terminal.

FIG. 7 is a cross-sectional view showing a variation of the external terminal.

FIG. 8A is a top view showing a step in a method of fabricating the semiconductor device of the embodiment.

FIG. 8B is a cross-sectional view taken along line VIIIb-VIIIb of FIG. 8A.

FIG. 9A is a top view showing a step in a method of fabricating the semiconductor device of the embodiment.

FIG. 9B is a cross-sectional view taken along line IXb-IXb of FIG. 9A.

FIG. 10A is a top view showing a step in a method of fabricating the semiconductor device of the embodiment.

FIG. 10B is a cross-sectional view taken along line Xb-Xb of FIG. 10A.

FIG. 11A is a top view showing a step in a method of fabricating the semiconductor device of the embodiment.

FIG. 11B is a cross-sectional view taken along line XIb-XIb of FIG. 11A.

FIG. 12A is a top view showing a step in a method of fabricating the semiconductor device of the embodiment.

FIG. 12B is a cross-sectional view taken along line XIIb-XIIb of FIG. 12A.

FIG. 13A is a top view showing a variation of the semiconductor device of the embodiment.

FIG. 13B is a cross-sectional view taken along line XIIIb-XIIIb of FIG. 13A.

### DETAILED DESCRIPTION

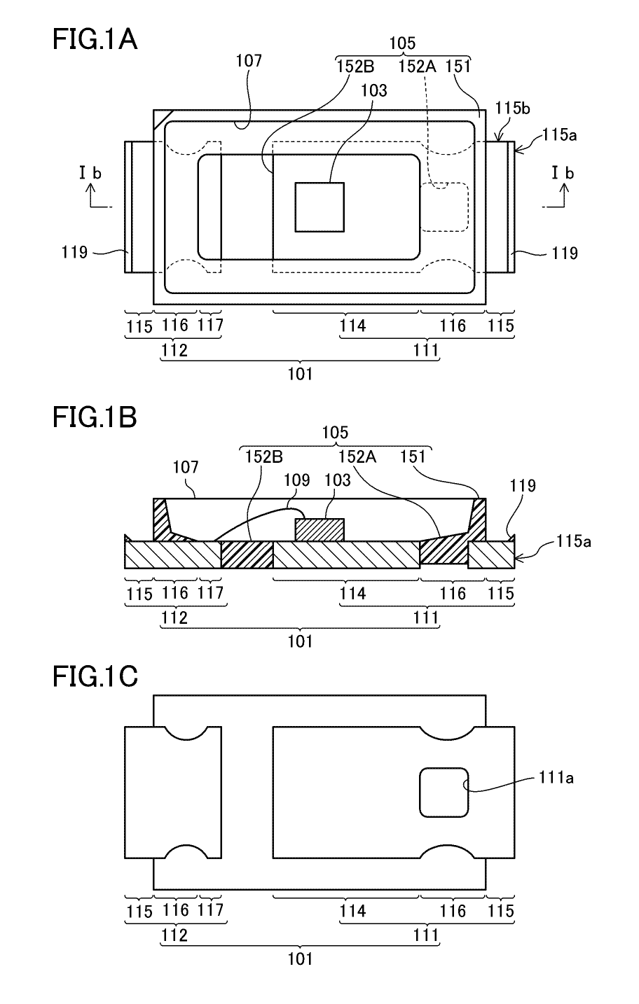

FIG. 1A is a plan view of a structure of a semiconductor device according to an embodiment. FIG. 1B is a cross-sectional view of the structure of the semiconductor device, taken along line Ib-Ib of FIG. 1A. FIG. 1C is a bottom view of the structure of the semiconductor device.

As shown in FIG. 1, the semiconductor device of this embodiment includes a lead frame 101, a semiconductor element 103 mounted on the lead frame 101, a frame-like member 105 formed on the lead frame 101, surrounding the semiconductor element 103, and a protective resin 107 which fills a space surrounded by the frame-like member 105. In this embodiment, the semiconductor element 103 is, but is not limited to, a light emitting diode (LED).

The lead frame 101 is made of, for example, a copper (Cu)-based alloy having a thickness of about 0.15-0.3 mm. A top surface, a bottom surface, etc. of the lead frame 101 are typically covered with a plating layer (not shown). The lead frame 101 has a die pad portion 111 on which the semiconductor element 103 is mounted and a lead portion 112 which is separated from the die pad portion 111. The die pad portion 111 is located inside the frame-like member 105, and has an element mounting portion 114 on which the semiconductor element 103 is mounted and an external terminal 115 which protrudes outside the frame-like member 105. A constricted portion 116 which is narrower than the element mounting portion 114 and the external terminal 115 is formed between the element mounting portion 114 and the external terminal 115. A through hole 111a is formed in the constricted portion 116. The lead portion 112 is located inside the frame-like member 105, and has a wire bonding portion 117 to which a wire 109 is bonded and an external terminal 115 which protrudes outside the frame-like member 105. A constricted portion 116 which is narrower than the wire bonding portion 117 and the external terminal 115 is formed between the wire bonding portion 117 and the external terminal 115.

The frame-like member 105 is made of a resin etc., and has a wall portion 151 which surrounds an outer edge portion of the lead frame 101, a buried portion 152A which is buried in the through hole 111a of the die pad portion 111, and a buried portion 152B which is buried in a gap between the die pad portion 111 and the lead portion 112. The wall portion 151, the buried portion 152A, and the buried portion 152B are integrally formed. In this embodiment, the frame-like member 105 is formed to cover side surfaces of the lead frame 101 and expose a bottom surface of the lead frame 101. The outer perimeter of the wall portion 151 has a planar and rectangular shape. The external terminal 115 of the die pad portion 111 protrudes outside the frame-like member 105 from one of the shorter sides, and the external terminal 115 of the lead portion 112 protrudes outside the frame-like member 105 from the other shorter side.

The semiconductor element 103 is mounted on the element mounting portion 114 of the die pad portion 111. In FIG. 1, a back electrode (not shown) is formed on a back surface of the semiconductor element 103, and the back electrode and the element mounting portion 114 are bonded together by a conductive paste, such as solder etc. In this embodiment, the element mounting portion 114 of the die pad portion 111 spreads on both sides of a center line passing through a middle in a longitudinal direction of the frame-like member 105, and the semiconductor element 103 is disposed at a center of a region surrounded by the frame-like member 105. In this embodiment, the entire semiconductor device including the external terminals 115 protruding outside the frame-like member 105 are axially symmetric, and therefore, the semiconductor element 103 is disposed at a center of the semiconductor device. A top electrode (not shown) is formed on a top surface of the semiconductor element 103. The top electrode and the wire bonding portion 117 of the lead portion 112 are connected together via the wire 109.

The space surrounded by the frame-like member 105 is filled with the protective resin 107 which is a transparent resin. As a result, the semiconductor element 103 and the wire 109 are encapsulated. The protective resin 107 may contain a fluorescent material which absorbs light emitted by the semiconductor element 103 to emit light having a different wavelength.

The external terminals 115 of the die pad portion 111 and the lead portion 112 each have a barrier portion 119 raised from the top surface at an end portion thereof opposite to the frame-like member 105. If the protective resin 107 flows over the frame-like member 105 or leaks out from an interface between the frame-like member 105 and the lead frame 101, the protective resin 107 spreads on the top surface of the external terminal 115. If the barrier portion 119 is not provided, then when the amount of a leaking protective resin is large, the leaking protective resin reaches a side surface of the external terminal 115. If the amount is still larger, the protective resin reaches a back surface of the external terminal 115. When soldering is performed on the semiconductor device, the side and bottom surfaces of the external terminal 115 are covered with a solder fillet. Of the side surfaces of the external terminal 115, an end surface (front-end surface) 115a of the end portion of the external terminal 115 protruding from the frame-like member 105 is more important than side end surfaces 115b when soldering is performed on the semiconductor device. If the protective resin adheres to the front-end surface 115a, the formation of the solder fillet becomes insufficient, so that a faulty connection may occur or the bonding strength may decrease. However, because the semiconductor device of this embodiment has the barrier portion 119, the protective resin flowing onto the front-end surface 115a can be reduced or prevented.

The barrier portion 119 may be formed in any manner. For example, if the lead frame 101 is cut off a rail under conditions that burrs are likely to occur, the barrier portion 119 having a height of about several micrometers to about 10 μm can be formed at the end portion of the lead frame 101. Alternatively, when plating is performed on a surface of the lead frame 101, then if only a predetermined portion of the plating layer is caused to be thicker, the barrier portion 119 may be formed. Alternatively, after plating, the lead frame may be cut off in a manner which allows the plating layer to be peeled and lifted at the end portion of the lead frame 101, whereby the barrier portion 119 made of the plating layer may be formed at the end portion. In addition to these techniques, the barrier portion 119 may be formed by attaching a member made of a resin, a metal, etc. to a predetermined portion. When the barrier portion 119 is formed as burrs, the barrier portion 119 is made of the same material as that of the lead frame. Alternatively, the barrier portion 119 may be made of a multilayer including the material of the base and the material of the plating layer.

A preferable height from the top surface of the external terminal 115 to a top end of the barrier portion 119 are several micrometers, but varies depending on the viscosity of the protective resin. If the height is about 1-2 p.m or more, the effect of reducing or preventing the overflow of the protective resin is obtained. The effect increases with an increase in the height, but it is difficult to form the barrier portion 119 having an excessive height. Even when the barrier portion 119 is formed as burrs or plating, then if the height is about 10 p.m, the barrier portion 119 can be easily formed. In particular, when the barrier portion 119 is formed as burrs, then if the height is about one thirtieth of the thickness of the lead frame 101, the barrier portion 119 can be easily formed.

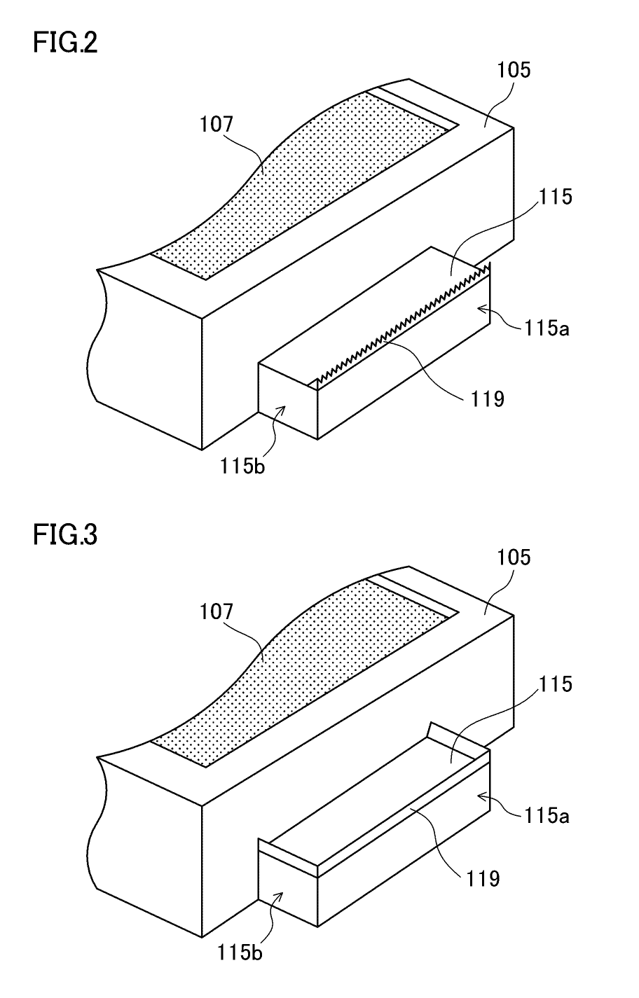

The barrier portion 119 does not need to have a flat top surface. As shown in FIG. 2, the top surface may have a sawtooth shape having a plurality of crests and troughs. A height from the top surface of the external terminal 115 to a top end of the trough is lower than a height from the top surface of the external terminal 115 to a top end of the crest. Even when there are the troughs having such a lower height, surface tension occurs between the crest and the trough, and therefore, the leakage reduction or prevention effect can be expected at a similar or higher level than that of the flat barrier portion 119.

FIG. 1 shows the example in which the barrier portion 119 is formed at an end portion protruding from the frame-like member 105 to protect the most important front-end surface 115a of the external terminal 115. As shown in FIG. 3, however, the barrier portion 119 may be formed to surround the outer edge portion of the external terminal 115 excluding a side thereof closer to the frame-like member 105. In this case, it is possible to reduce or prevent the overflow of the protective resin not only to the front-end surface 115a of the external terminal 115, but also to the side end surface 115b of the external terminal 115. Note that the top end portion of the barrier portion 119 may have a sawtooth shape.

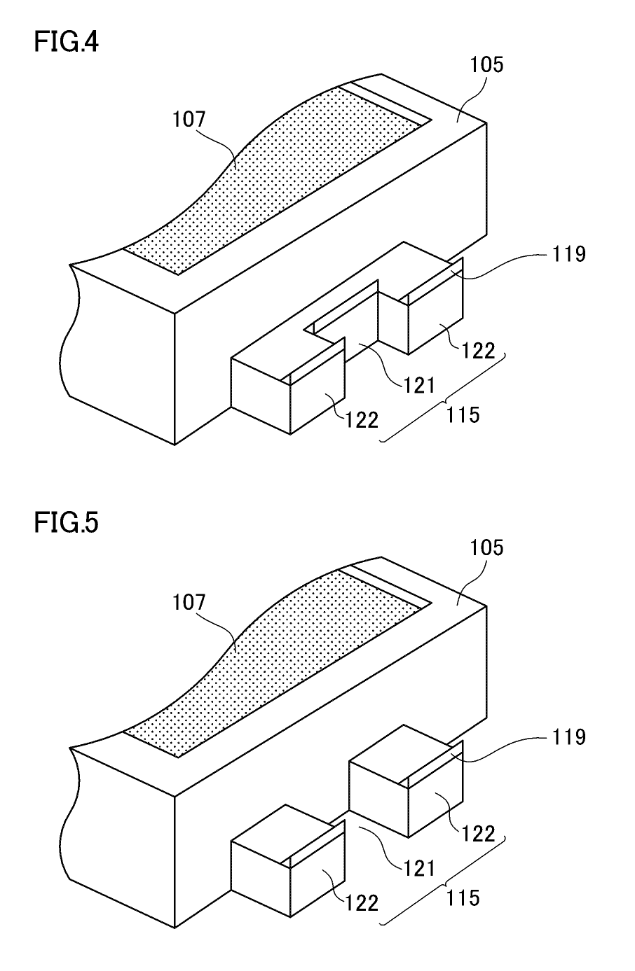

A width (protrusion width) of the external terminal 115 in a direction along the longer side of the frame-like member 105, and a width of the external terminal 115 in a direction along the shorter side of the frame-like member 105, may be set to any values. For example, the width of the external terminal 115 in a direction along the shorter side of the frame-like member 105 may be greater than or equal to the length of the shorter side of the frame-like member 105. Alternatively, as shown in FIG. 4, the external terminal 115 may have a concave portion 121 which has a smaller protrusion width than those of portions (convex portions 122) on both sides of the concave portion 121. In this case, the solder fillet can be trapped by the concave portion 121 and the convex portions 122 on both sides of the concave portion 121, so that soldering can be more easily performed. In addition, when the lead frame 101 is cut off the rail, mechanical stress applied to the lead frame 101 can be reduced. Also in this case, the barrier portion 119 may have a sawtooth top end portion, or the barrier portion 119 may be formed to surround the outer edge portion of the external terminal 115. Alternatively, the barrier portion 119 may not be formed at a center portion of the external terminal 115. Also in this case, the most important front-end surface 115a can be protected. Moreover, as shown in FIG. 5, the concave portion 121 may not protrude from the frame-like member 105. A width of the concave portion 121 in a direction along the shorter side of the frame-like member 105 may be set to any value and may be greater than that of the convex portion 122. The convex portions 122 do not need to have the same size. A plurality of concave portions 121 may be provided at a center, and three or more convex portions 122 may be provided.

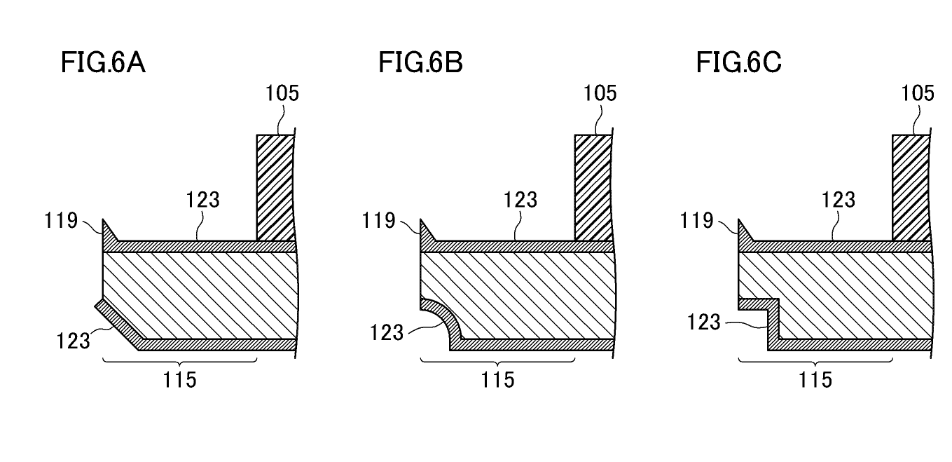

The front-end surface 115a of the external terminal 115 may have a notch portion at a lower portion thereof. By providing the notch portion, solder and the external terminal 115 can be more firmly bonded together. As shown in FIG. 6A, the notch portion may be formed by beveling, or cutting at an inclination, a lower end portion of the front-end surface 115a, in a cross-section thereof in the protrusion direction of the frame-like member 105. Alternatively, the bevel may have a curved shape (FIG. 6B) or an L-shape (FIG. 6C). By providing such a notch portion at the lower portion of the external terminal 115, the solder fillet can be more easily trapped (anchoring effect). The notch portion may extend over about half, or more than half, the front-end surface. Even if the notch portion extends over less than half the front-end surface, the anchoring effect can be obtained.

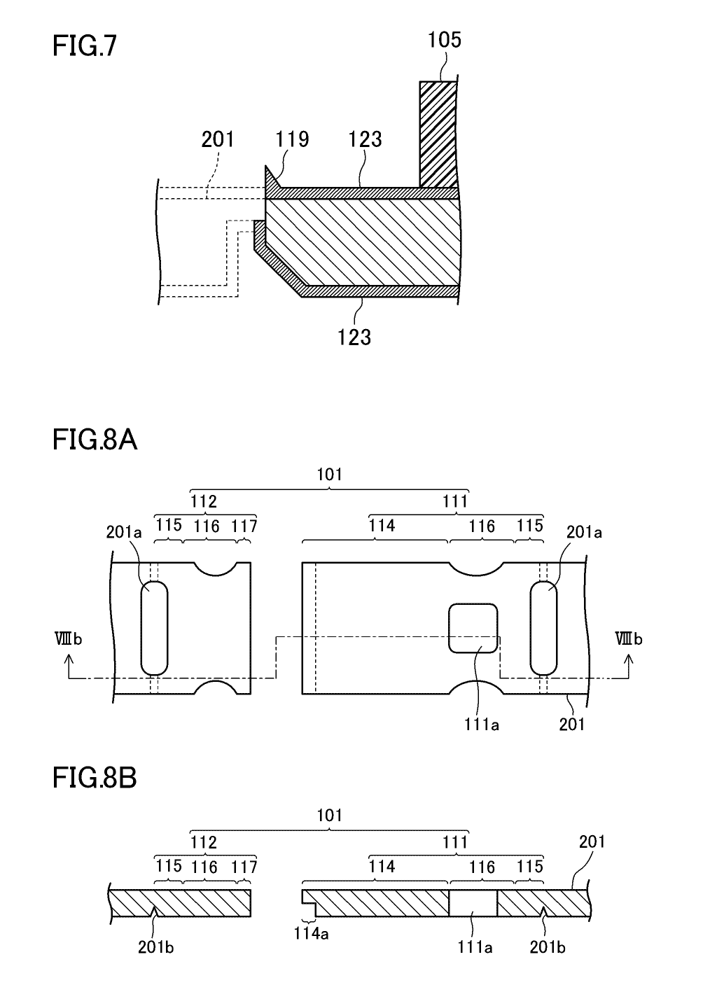

Typically, a plating layer 123 is formed on the top, back, and side surfaces of the lead frame 101 by a plating process. The plating process is typically performed before the lead frame 101 is cut off the rail. Therefore, the plating layer 123 is typically not formed on the front-end surface 115a of the external terminal 115, so that the base is exposed. When the notch portion is formed, the plating layer is formed on the notch portion as shown in FIGS. 6A-6C. Moreover, as shown in FIG. 7, if the plating layer 123 is also formed on a portion of the front-end surface 115a of the external terminal 115, the anchoring effect which allows a solder fillet to be easily trapped can be enhanced. For example, as shown in FIG. 7, the plating layer 123 may be provided on a portion of the front-end surface 115a of the external terminal 115 by reducing the thickness of a portion where the lead frame 101 is attached to the rail 201, forming the plating layer 123, and cutting the attachment portion.

When the external terminal 115 is cut off the rail 201 after the plating layer 123 is formed, then if the plating layer 123 is peeled and lifted, the barrier portion 119 made of the plating layer 123 can be formed as shown in FIGS. 6A-6C and FIG. 7. Note that the plating layer 123 may be made of lead-free solder, gold, silver, nickel, etc. In the case of silver, a sulfuration prevention process may be further performed. Alternatively, the plating layer 123 may be made of a multilayer of nickel and silver, a multilayer of nickel, gold, and silver, etc.

FIGS. 8A-12B show a method for fabricating the semiconductor device of this embodiment in the order in which the device is fabricated. Initially, as shown in FIGS. 8A and 8B, the lead frame 101 which is attached to the rail 201 is formed at a predetermined portion of a base by etching, stamping, etc. Thereafter, plating is optionally performed to form a plating layer (not shown). Note that plating may be performed before the etching or stamping process. The lead frame 101 is not limited to any particular shape, but is assumed to have a structure described below.

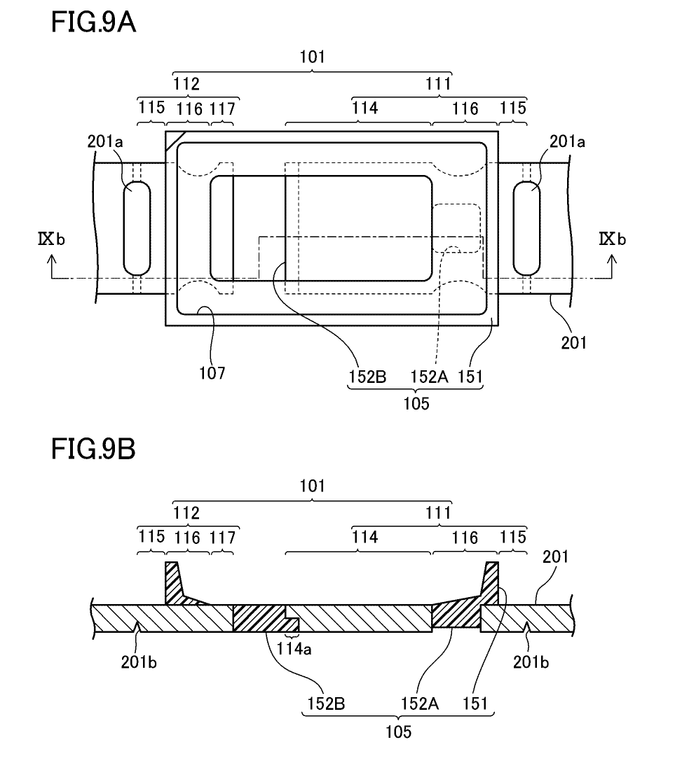

The die pad portion 111 of the lead frame 101 has the element mounting portion 114, the external terminal 115, and the constricted portion 116 formed between the external terminal 115 and the element mounting portion 114. The constricted portion 116 is narrower than the element mounting portion 114 and the external terminal 115. The through hole 111a is formed at a center portion of the constricted portion 116. An opening 201 a is formed at a portion where the external terminal 115 is attached to the rail 201, so that the attachment portion of the external terminal 115 and the rail 201 is narrowed. A groove 201b is formed in the back surface of the attachment portion. A lower portion of an end portion on the element mounting portion 114 side of the die pad portion 111 is removed to form a thin portion 114a which is thinner than the other portion of the die pad portion 111. In FIG. 8, the external terminal 115 is as wide as the element mounting portion 114. Alternatively, the external terminal 115 may be wider or narrower than the element mounting portion 114. The lead portion 112 is formed, facing the end portion on the element mounting portion 114 side of the die pad portion 111, with a space between the lead portion 112 and the die pad portion 111. The lead portion 112 has the wire bonding portion 117, the external terminal 115, and the constricted portion 116 formed between the wire bonding portion 117 and the external terminal 115. An opening 201a is formed at a portion where the external terminal 115 is attached to the rail 201. A groove 201b is formed in the back surface of the attachment portion. In FIG. 8, the external terminal 115 is as wide as the wire bonding portion 117. Alternatively, the external terminal 115 may be wider or narrower than the wire bonding portion 117. The external terminal 115 of the lead portion 112 may or may not be as wide as the external terminal 115 of the die pad portion 111. Next, as shown in FIG. 9, the frame-like member 105 is formed. The frame-like member 105 may be formed by, but not limited to, commonly used insert molding, etc. The frame-like member 105 may be made of, for example, a thermoplastic resin containing a polyamide etc. as a major component or a thermosetting resin containing silicone etc. as a major component. Alternatively, the frame-like member 105 may be made of other resin materials. In the molding process, the frame-like member can be easily formed using the through hole 111a of the die pad portion 111 as a gate for injection of the resin. The frame-like member 105 is formed along the outer edge portion of the lead frame 101, and has the wall portion 151 rising from the top surface of the lead frame 101, the buried portion 152A buried in the through hole 111a of the die pad portion 111, and the buried portion 152B buried between the die pad portion 111 and the lead portion 112. A shorter side of the frame-like member 105 is positioned on the constricted portion 116, leaving the external terminal 115 to protrude outside the frame-like member 105.

If an inner wall of the wall portion 151 is allowed to have a sloped surface, the wall portion 151 is easily molded. If the buried portion 152A is allowed to have a top surface sloped at an angle smaller than that of the inner wall of the wall portion 151, the buried portion 152A is easily formed. If the bottom surface of the buried portion 152A is located higher than the bottom surface of the die pad portion 111, an inner wall surface of the through hole 111a is expected to provide the anchoring effect during soldering. Note that the bottom surfaces of the buried portion 152A and the die pad portion 111 may form a flat surface. The adhesion between the frame-like member 105 and the lead frame 101 may decrease when the frame-like member 105 is formed of some resin materials. In this embodiment, however, the lead frame 101 has the constricted portion 116, the through hole 111a, the thin portion 114a, etc. This structure can enhance the adhesion between the frame-like member 105 and the lead frame 101. The strength of the frame-like member 105 can also be enhanced. Therefore, even when a thermoplastic resin, which has excellent recyclability, is used, a sufficient level of adhesion and strength can be ensured. Note that not all of the constricted portion 116, the through hole 111a, the thin portion 114a, etc. are required, and only a portion or none of them may be provided.

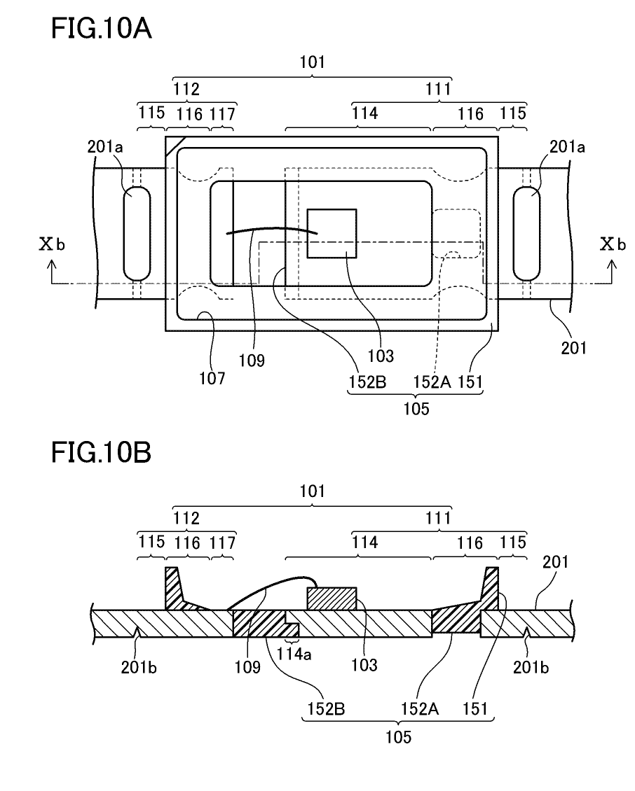

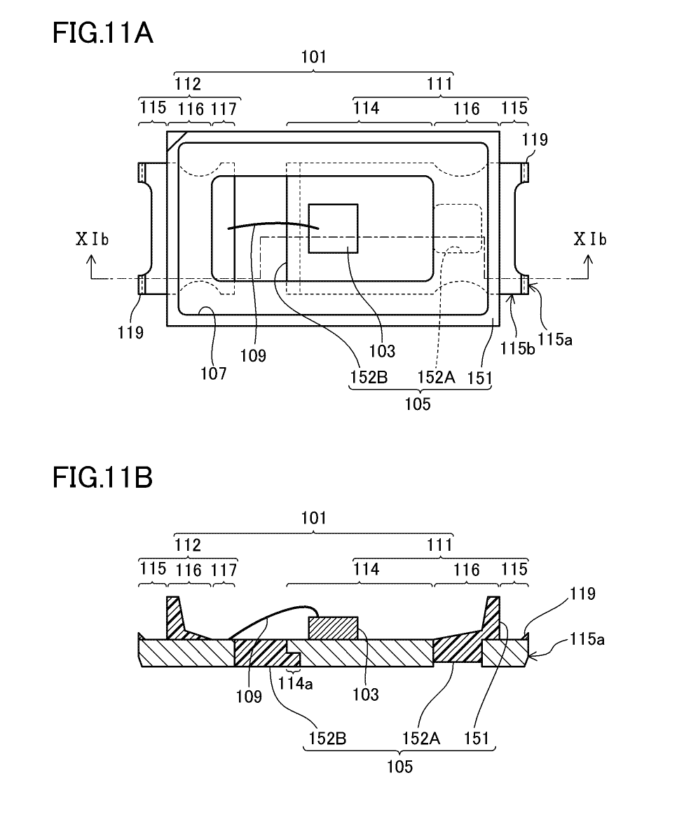

Next, as shown in FIG. 10, the semiconductor element 103 is fixed to the element mounting portion 114. Thereafter, the electrode provided on the top surface of the semiconductor element 103 is connected to the wire bonding portion 117 of the lead portion 112 via the wire 109. When the semiconductor element 103 has a back electrode, the semiconductor element 103 may be fixed using a conductive paste, such as solder etc. When the semiconductor element 103 does not have a back electrode, a portion of the element mounting portion 114 may be used as a bonding pad to connect the electrode formed on the top surface of the semiconductor element 103 to the die pad portion 111 via a wire. When the semiconductor element 103 is a light emitting element, a photodetector element, etc., the semiconductor element 103 is preferably mounted at a center of the frame-like member 105. To this end, the die pad portion 111 preferably extends from one of the shorter sides of the frame-like member 105 to a midpoint between the middle of the longer side and the other shorter side. Note that some types of semiconductor elements do not necessarily need to be mounted at a center of the frame-like member 105.

Next, as shown in FIG. 11, the lead frame 101 is cut off the rail 201 at the groove 201b. In this case, if a cutting blade is moved upward from the back surface in which the groove 201b is formed, burrs projecting upward occur on the top surface of the external terminal 115 to form the barrier portion 119. Alternatively, the barrier portion 119 may be formed by peeling and lifting a plating layer. Note that the barrier portion 119 may be formed by causing burrs to occur when the opening 201a is formed. The barrier portion 119 may be a separate part which is attached to the top surface of the external terminal 115. A notch portion may be formed at an end portion of the external terminal 115 by previously forming a V-shaped groove 201b.

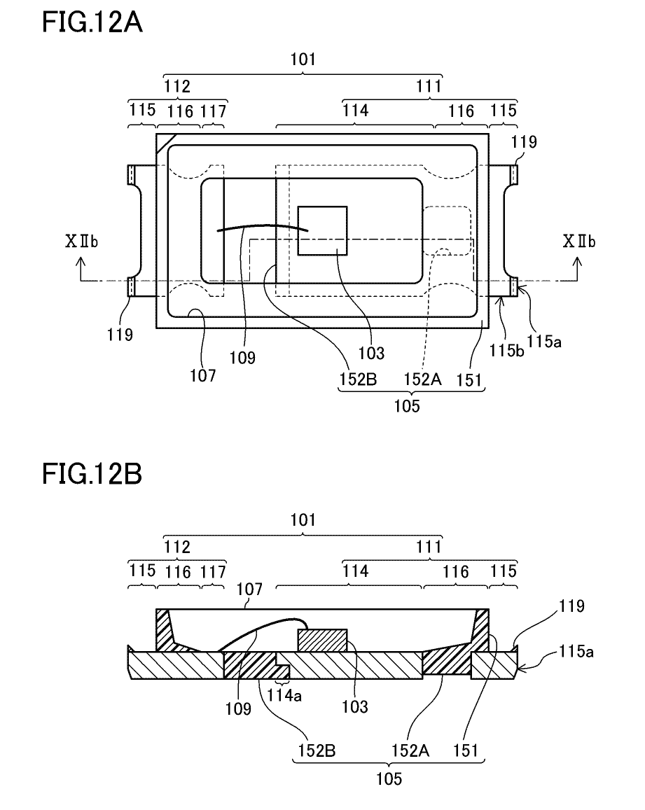

Next, as shown in FIG. 12, a space inside the frame-like member 105 is filled with the protective resin 107. Even if the protective resin 107 leaks out, the barrier portion 119 makes it difficult for the protective resin 107 to reach the end surface and back surface of the external terminal 115, so that a defect can be reduced or prevented. Note that an electrical characteristic may be optionally tested after the lead frame 101 is cut off the rail 201 and before the space inside the frame-like member 105 is filled with the protective resin 107.

Note that the process, the structure of the lead frame 101, etc. may be modified and changed as appropriate. For example, the lead frame 101 may be cut off the rail 201 before the semiconductor element 103 is mounted. A thin portion may be provided in the lead portion 112 in addition to the die pad portion 111.

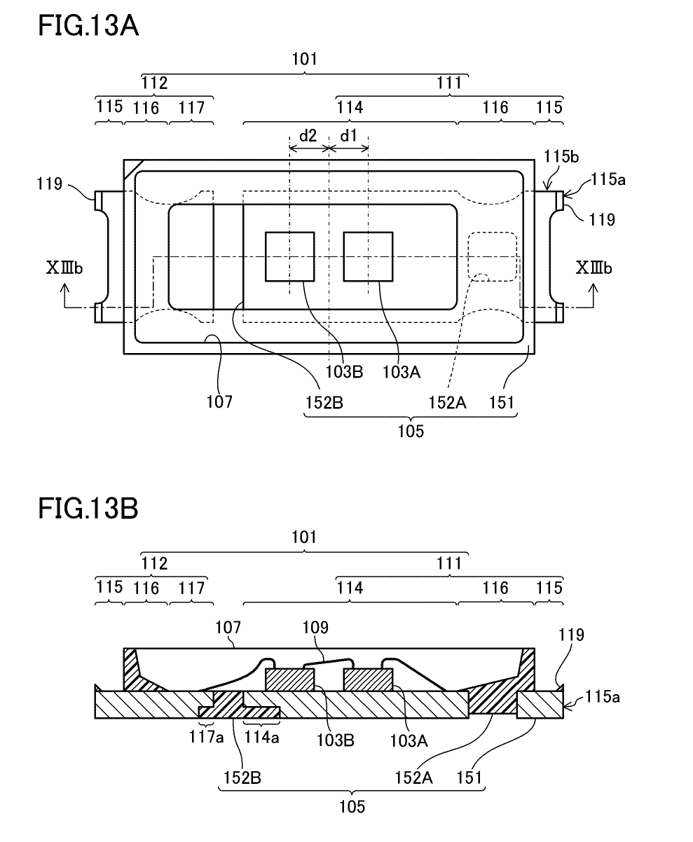

Although an example in which a single semiconductor element is mounted has been described above, a plurality of semiconductor elements may be mounted on the die pad portion 111. If a plurality of semiconductor elements for which optical characteristics are required, such as light emitting elements, photodetector elements, etc., are mounted, the semiconductor elements are preferably disposed at axially symmetric positions with respect to a center line passing through a middle in the longitudinal direction of the frame-like member 105. Specifically, as shown in FIG. 13, a distance dl between the center line and a first semiconductor element 103A and a distance d2 between the center line and a second semiconductor element 103B may be set to be equal to each other. When a plurality of semiconductor elements are mounted, the size of the die pad portion 111 increases. Therefore, in order to reduce the size of the semiconductor device, the space between the die pad portion 111 and the lead portion 112 needs to be reduced. In this case, in order to reduce or prevent a short circuit caused by a solder bridge on the back surface of the lead frame 101, a thin portion 114a and a thin portion 117a are preferably provided at an end portion of the die pad portion 111 closer to the lead portion 112 and an end portion of the lead portion 112 closer to the die pad portion 111, respectively. With this structure, a short circuit is less likely to occur, and in addition, the adhesion between the frame-like member 105 and the lead frame 101 can be enhanced. Also, at least a portion of the second semiconductor element 103B closer to the lead portion 112 than to the center line is preferably disposed on the thin portion 114a. As a result, the area of the die pad portion 111 can be reduced while a sufficient region where the semiconductor element(s) 103 is mounted is ensured.

Although an example in which only a semiconductor element is mounted on a lead frame has been described above, a resistor, a capacitor, etc. may be mounted together with the semiconductor element. Although an example in which two external terminals are formed has been described above, a plurality of lead portions and three or more external terminals may be formed. The semiconductor element is not limited to light emitting elements (e.g., light emitting diodes, superluminescence diodes, laser diodes, etc.), photodetector elements, etc., and may be other types of transistors, diodes, sensors, etc. The protective resin may optionally be made of a light shield material. Although an example in which the back surface of the lead frame is exposed has been described above, at least a portion of the back surface of the lead frame may be covered by the frame-like member. Although an example in which a semiconductor device has a rectangular frame-like member has been described above, a square frame-like member may be employed. Alternatively, the frame-like member may be in the shape of a polygon, a circle, an ellipse, an oval, etc.

As described above, in the semiconductor device of the present disclosure, even if a protective resin leaks out, an incorrect or defective mounting is less likely to occur. The present disclosure is particularly useful for semiconductor devices including a lead frame.

What is claimed is:

1. A semiconductor device comprising:
a lead frame;
a first semiconductor element mounted on a main surface of the lead frame;
a frame-like member formed on the lead frame, surrounding the first semiconductor element; and
a protective resin filling a space surrounded by the frame-like member, wherein
the lead frame has an external terminal protruding outside the frame-like member, and
the external terminal has a barrier portion which is located at an end portion thereof protruding from the frame-like member and rises from the main surface in a direction in which the first semiconductor element is mounted.

2. The semiconductor device of claim 1, further comprising:
a second semiconductor element mounted on the lead frame, wherein
the lead frame has a die pad portion on which the first and second semiconductors element are mounted and a lead portion separated from the die pad portion,
the die pad portion has a thin portion at an end portion thereof opposite to the external terminal, the thin portion being thinner than the other portion of the die pad portion, and
at least a portion of the second semiconductor element is disposed on the thin portion.

3. The semiconductor device of claim 2, wherein
the first and second semiconductor elements are disposed at axially symmetric positions with respect to a center line of the frame-like member.

4. The semiconductor device of claim 1, wherein the lead frame has a die pad portion on which the first semiconductor element is mounted and a lead portion separated from the die pad portion, and the first semiconductor element is disposed at a middle of the frame-like member.

5. The semiconductor device of claim 4, wherein
the die pad portion has a through hole,
the frame-like member has a wall portion rising from the main surface of the lead frame and a buried portion which is buried in the through hole and is integrally formed with the wall portion, and
a bottom surface of the buried portion is located higher than a bottom surface of the die pad portion.

6. The semiconductor device of claim 5, wherein
a portion of the die pad portion in which the through hole is formed is narrower than the other portion of the die pad portion.

7. The semiconductor device of claim 1, wherein
the lead frame has a plating layer, except for at least a portion of an end surface of the external terminal, the end surface extending in a direction parallel to a wall surface of the frame-like member.

8. The semiconductor device of claim 7, wherein
the barrier portion is made of the same material as that of the plating layer.

9. The semiconductor device of claim 1, wherein
the barrier portion has a plurality of crests and a plurality of troughs lower than the crests.

10. The semiconductor device of claim 1, wherein
the barrier portion surrounds an outer edge portion of the main surface at the external terminal.

11. The semiconductor device of claim 1, wherein
the external terminal has a concave portion which has a smaller protrusion width than those of portions thereof on both sides of the concave portion.

12. The semiconductor device of claim 1, wherein
the external terminal has a notch portion at an end portion thereof protruding from the frame-like member.

13. The semiconductor device of claim 12, wherein
the notch portion is in shape of a straight line.

14. The semiconductor device of claim 12, wherein
the notch portion is in the shape of a curve.

15. The semiconductor device of claim 12, wherein the notch portion is in an L-shape.

16. The semiconductor device of claim 1, wherein
the protective resin is a translucent resin.

17. The semiconductor device of claim 16, wherein
the first semiconductor element is a light emitting element or a photodetector element.

18. The semiconductor device of claim 1, wherein
the frame-like member is made of a thermoplastic resin.
